(19) United States
(12) Patent Application Publication
(10) Pub. No.: US 2011/0110058 A1
(43) Pub. Date: May 12, 2011

(54) BOARD ON CHIP PACKAGE SUBSTRATE AND MANUFACTURING METHOD THEREOF

(75) Inventors: Ji-Eun KIM, Gwangmyung-si (KR); Nam-Keun Oh, Yusung-gu (KR); Jung-Hyun Park, Hwasung-si (KR); Young-Ji Kim, Seo-gu (KR); Jong-Gyu Choi, Youngi-gun (KR); Sang-Duck Kim, Chungjoo-si (KR); Young-Hwan Shin, Yoosung-gu (KR); Kyung-Ro Yoon, Yoosung-gu (KR)

(73) Assignee: SAMSUNG ELECTRO-MECHANICS CO., LTD.

(21) Appl. No.: 12/748,082

(22) Filed: Mar. 26, 2010

(30) Foreign Application Priority Data
Nov. 11, 2009 (KR) 10-2009-0108718

(51) Int. Cl. H05K 7/02; H05K 3/00

(52) U.S. Cl. 361/767; 29/829

(57) ABSTRACT

A single-layer board on chip package substrate and a manufacturing method thereof are disclosed. In accordance with an embodiment of the present invention, the single-layer board on chip package substrate includes an insulator, a circuit pattern and a flip-chip bonding pad, which are formed on an upper surface of the insulator, a conductive bump, which is in contact with a lower surface of the circuit pattern and penetrates through the insulator, a solder resist layer, which is formed on the upper surface of the insulator such that at least a portion of the flip-chip bonding pad is exposed, and a flip-chip bonding bump, which is formed on an upper surface of the flip-chip bonding pad in order to make a flip-chip connection with an electronic component.

### CROSS-REFERENCE TO RELATED APPLICATIONS

This application claims the benefit of Korean Patent Application No. 10-2009-0108718, filed with the Korean Intellectual Property Office on Nov. 11, 2009, the disclosure of which is incorporated herein by reference in its entirety.

### BACKGROUND

1. Technical Field

The present invention is related to a single-layer board on chip package substrate and a manufacturing method thereof.

2. Description of the Related Art

Compared to the conventional electronic devices, the latest electronic devices are becoming increasingly thinner. For this, there has been a demand for smaller-size, higher-performance semiconductor chip packages. With the current trend, a multi-chip package, in which a plurality of semiconductor chips are vertically stacked or arranged in a flat surface while embedded in the package, and a board on chip package, in which a semiconductor chip is attached directly to the board and the overall size is reduced by sealing it, are used for semiconductor chip packages.

The board on chip (BOC) is receiving attention as a next generation high-speed semiconductor substrate that is suitable for high-speed DRAM, such as DDR2, because a bare die itself is placed directly on a substrate, by which thermal and electrical losses due to the high-speed of DRAM can be minimized, unlike the conventional method in which a semiconductor is mounted on a substrate by using a lead frame. The current capacity of DRAM is rapidly increasing to, for example, 128 MB, 256 MB, 512 MB, 1 GB and 2 GB. In response to a trend toward higher-performance DRAMs, electrical losses have to be minimized by reducing the thickness of the substrate, and the product reliability has to be improved. In the conventional board on chip package, a hole for connecting a semiconductor chip is formed in the center of the substrate, and wire bonding is implemented by the hole.

Even in this conventional board on chip package, the increased number of input/output terminals for higher-density has become a problem, and thus there have been demands for saving the cost of manufacturing the printed circuit board.

### SUMMARY

The present invention provides a single-layer board on chip package substrate and a method of manufacturing the same that can implement higher-density and save the production cost.

An aspect of the present invention provides a single-layer board on chip package substrate that includes an insulator, a circuit pattern and a flip-chip bonding pad, which are formed on an upper surface of the insulator, a conductive bump, which is in contact with a lower surface of the circuit pattern and penetrates through the insulator, a solder resist layer, which is formed on the upper surface of the insulator such that at least a portion of the flip-chip bonding pad is exposed, and a flip-chip bonding bump, which is formed on an upper surface of the flip-chip bonding pad in order to make a flip-chip connection with an electronic component.

The single-layer board on chip package substrate can further include a solder ball, which is coupled to a lower surface of the conductive bump penetrating through the insulator, and an electronic component, which is mounted on an upper side of the insulator by making a flip-chip connection with the flip-chip bonding pad through the flip-chip bonding bump.

The circuit pattern and the flip-chip bonding pad can be buried in the insulator.

Another aspect of the present invention provides a method of manufacturing a single-layer board on chip package substrate. The method includes preparing a bump substrate, which includes forming a circuit pattern and a flip-chip bonding pad on a surface of a carrier, forming a conductive bump on a surface of the circuit pattern and stacking an insulator on the surface of the carrier and in which the insulator is penetrated by the conductive bump and the circuit pattern and the flip-chip bonding pad are buried in the insulator, removing the carrier, in which the circuit pattern and the flip-chip bonding are exposed, forming a solder resist layer on a surface of the insulator such that the circuit pattern is covered and at least a portion of the flip-chip bonding pad is exposed and forming a flip-chip bonding bump on an upper surface of the flip-chip bonding pad in order to make a flip-chip connection with an electronic component.

The method can further include coupling a solder ball to an end part of the conductive bump having penetrated through the insulator and mounting an electronic component on an upper side of the insulator in such a way that the electronic component makes a flip-chip connection with the flip-chip bonding pad through the flip-chip bonding bump.

The bump substrate can be formed in a pair, and the pair of bump substrates can be stacked by interposing a separator, prior to the removing of the carrier, in which all end parts of the conductive bump face the separator. The pair of bump substrates can be separated from the separator, after the forming of the solder resist layer.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a board on chip package substrate in accordance with an embodiment of the present invention.

FIG. 2 is a cross-sectional view illustrating an electronic component mounted on the board on chip package substrate of FIG. 1.

FIG. 3 is a flow chart illustrating a method of manufacturing a board on chip package substrate in accordance with an embodiment of the present invention.

FIGS. 4 to 11 are flow diagrams illustrating a method of manufacturing a board on chip package substrate in accordance with an embodiment of the present invention.

### DETAILED DESCRIPTION

As the invention allows for various changes and numerous embodiments, a particular embodiment will be illustrated in the drawings and described in detail in the written description. However, this is not intended to limit the present invention to a particular mode of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that A board on chip package substrate and a manufacturing method thereof according to a certain embodiment of the present invention will be described below in more detail with reference to the accompanying drawings. Those components that are the same or are in correspondence are rendered the same reference numeral regardless of the figure number, and redundant descriptions are omitted.

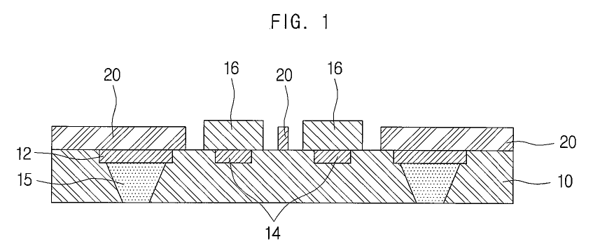

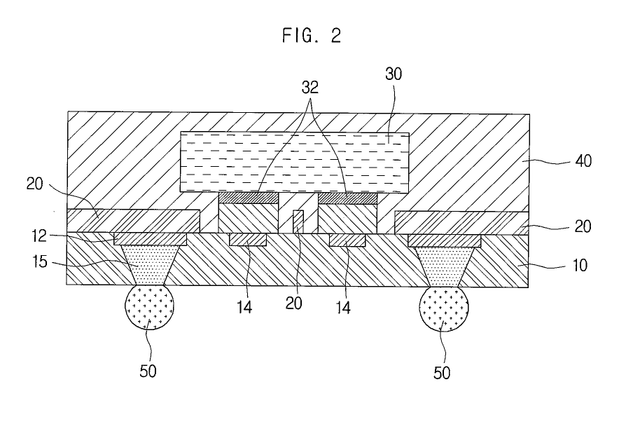

FIG. 1 is a cross-sectional view of a board on chip package substrate in accordance with an embodiment of the present invention, and FIG. 2 is a cross-sectional view illustrating an electronic component mounted on the board on chip package substrate of FIG. 1.

A circuit pattern 12 and a flip-chip bonding pad 14 are formed on an upper surface of an insulator 10. It is to be noted that the circuit pattern 12 emcompasses a wiring pattern that performs transmitting and receiving an electrical signal on the upper surface of the insulator 10 and a portion that is electrically connected to a solder ball 50 through a conductive bump 15, which will be described later. Meanwhile, the flip-chip bonding pad 14 can function as an input/output terminal transmitting and receiving a signal with an electronic component 30 mounted on the insulator 10.

Here, the circuit pattern 12 and the flip-chip bonding pad 14 can be buried in the insulator 10. By embedding the circuit pattern 12 and the flip-chip bonding pad 14 in the insulator 10, not only is there a less chance of short circuit between them, but also the overall thickness of the product can be reduced, even though minute pitch is implemented.

The insulator 10 is penetrated by the conductive bump 15. The conductive bump 15 is in contact with a lower surface of the circuit pattern 12, and an end part of the conductive bump 15 penetrating through the insulator 10 is connected to the solder ball 50, thereby transmitting and receiving a signal with a mother board and the like. That is, since the conductive bump 15 is used for connection between the circuit pattern 12, which is formed in an upper surface of the insulator 10, and the solder ball 50, the present embodiment of the present invention does not require any additional process of manufacturing and plating a hole. Moreover, since the solder ball 50 is coupled directly to the end part of the conductive bump 15, the present embodiment also does not require a process such as rewiring on a lower surface of the insulator 10.

A solder resist layer 20 is coated on the upper surface of the insulator 10. The solder resist layer 20 can be used to protect the circuit pattern 12 formed in the upper surface of the insulator 10. Here, the flip-chip bonding pad 14, which is an input/output terminal for transmitting and receiving a signal with the electronic component 30, can be exposed. Since the circuit pattern 12 is connected to the solder ball 50 through the lower surface, an upper surface of the circuit pattern 12 can be covered by the solder resist layer 20. An upper surface of the flip-chip bonding pad 14 can be completely exposed or partially exposed.

Meanwhile, a flip-chip bonding bump 16 can be printed on the upper surface of the flip-chip bonding pad 14 in order to make a flip-chip connection with the electronic component 30. By way of the flip-chip bonding bump 16, an electrode 32 of the electronic component 30 and the flip-chip bonding pad 14 can be electrically connected to each other.

Meanwhile, the electronic component 30 is mounted on an upper side of the insulator 10. Here, the electronic component 30 can be connected to the flip-chip bonding pad 14 by a flip-chip method. That is, the electronic component 30 is not mounted by a face-up method but mounted by a face-down method to be connected to the flip-chip bonding pad 14 through the flip-chip bonding bump 16. With this flip-chip connection, more input/output paths can be obtained, allowing an advantageous structure for higher-density.

As such, the electronic component 30 mounted on an upper side of the insulator 10 can be protected from the outside by being covered by a molding material 40.

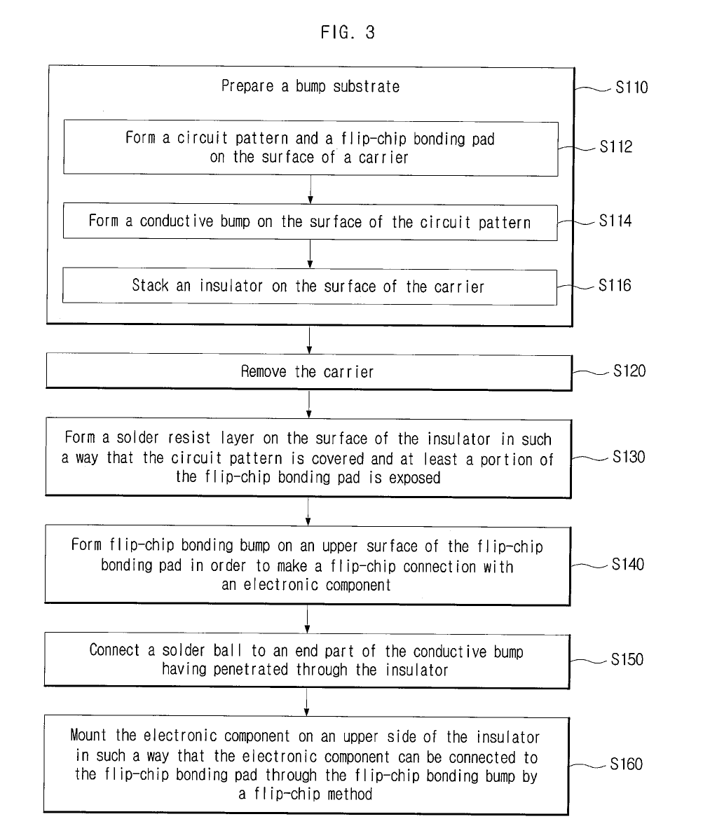

Hitherto, the structure of a board on chip package substrate in accordance with an embodiment of the present invention has been described. Hereinafter, a method of manufacturing the same will be described with reference to FIGS. 3 to 11.

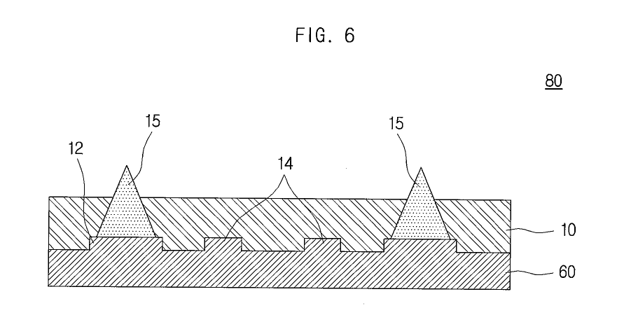

First of all, a bump substrate 80 is prepared (S110). It is to be noted that, as illustrated in FIG. 6, the bump substrate 80 means a structure having a carrier 60, in which a circuit pattern 12 and a flip-chip bonding pad 14 are formed on the surface, a conductive bump 15, which is printed on a surface of the circuit pattern 12, and an insulator 10, which is stacked on the carrier 60. A method of preparing the bump substrate 80 will be described in more detail hereinafter.

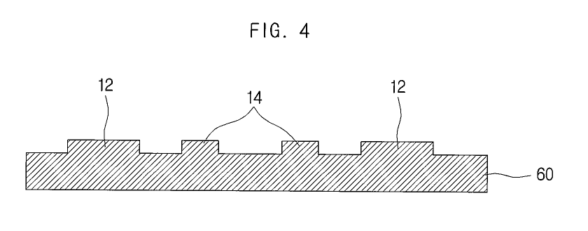

First, as illustrated in FIG. 4, the circuit pattern 12 and the flip-chip bonding pad 14 are formed on the surface of the carrier 60 (S112). For this, various methods, such as an additive method, a tenting method and/or an inkjet method, can be used. A metal plate or polymer film can be used as the carrier 60.

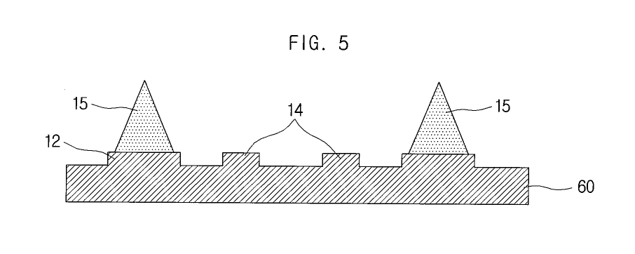

After this, the conductive bump 15 is formed on the surface of the circuit pattern 12, as illustrated in FIG. 5 (S114). For this, a conductive paste can be printed on the surface of the circuit pattern 12 by using a screen printing method or inkjet printing method and then be hardened.

Then, the insulator 10 is stacked on the surface of the carrier 60 (S116). This results in the bump substrate 80 in which the conductive bump 15 penetrates through the insulator 10 and the circuit pattern 12 and the flip-chip bonding pad 14 are buried in the insulator 10.

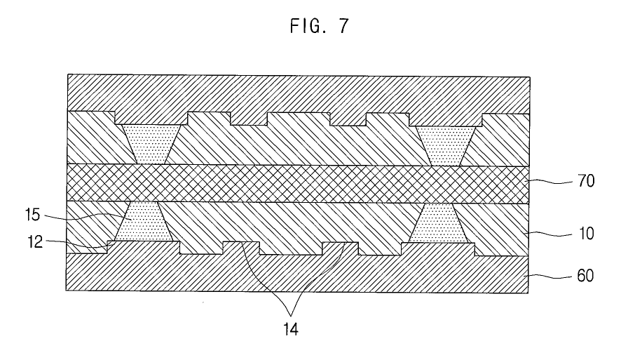

After preparing the bump substrate 80 as described above, the next processes can be performed. To perform a manufacturing process for a pair of bump substrates 80 at the same time, the pair of bump substrates 80 are prepared by repeating the above processes. Then, as illustrated in FIG. 7, the pair of bump substrates 80 are stacked by interposing a separator 70 between them, and then the next processes can be performed. In the description below, an example in which the pair of bump substrates 80 are simultaneously processed will be described.

Once the bump substrate 80 is prepared through the above processes, the pair of bump substrates 80 are stacked by interposing the separator 70 between them, as illustrated in FIG. 7. Here, all end parts of the conductive bump 15 penetrating through the insulator 10 face the separator 70. A thermoplastic material can be used for the separator 70.

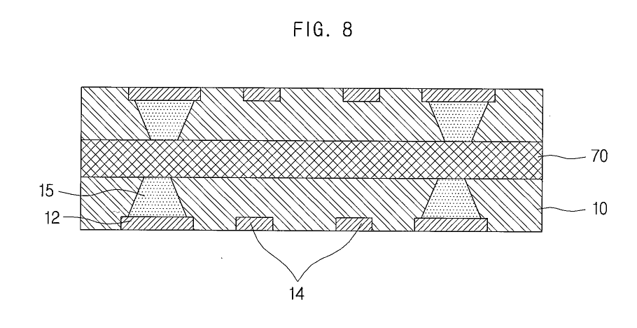

Then, the carrier 60 is removed, as illustrated in FIG. 8 (S120). If the carrier 60 is made of a metallic material, a wet-etching process can be used, and if the carrier 60 is made of a polymer film, a peeling process can be used. As such, once the carrier 60 is removed, the circuit pattern 12 and the flip-chip bonding pad 14 buried in the insulator 10 can be exposed.

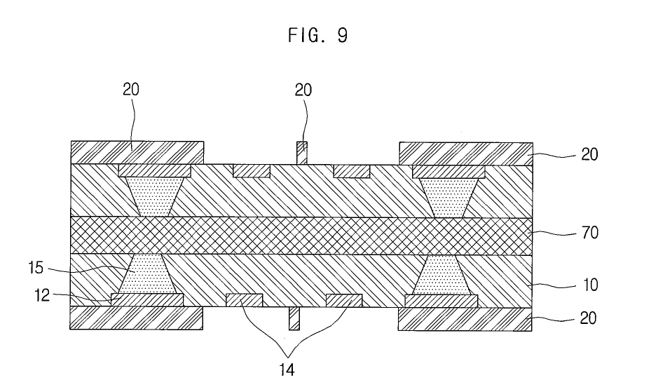

Next, the solder resist layer 20 is formed on the surface of the insulator 10 in such a way that the circuit pattern 12 is covered and at least a portion of the flip-chip bonding pad 14 is exposed, as illustrated in FIG. 9 (S130). For this, solder resist ink can be coated on an upper surface of the insulator 10, and then a portion thereof can be removed so as to expose a portion or all of the flip-chip bonding pad 14.

Then, the pair of bump substrates 80 are separated from the separator 70. If a thermoplastic material is used as the separator 70, a heating process can be performed prior to the separating of the pair of bump substrates 80 so as to weaken the adhesion of the separator 70.

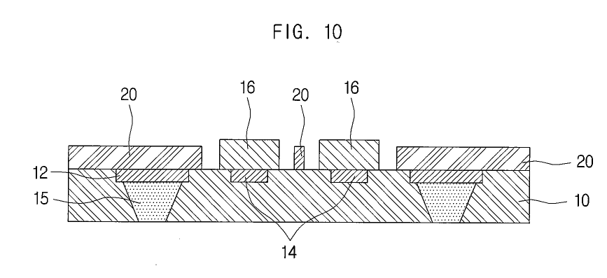

After these processes, the flip-chip bonding bump 16 is formed on an upper surface of the flip-chip bonding pad 14 in order to make a flip-chip connection with an electronic component 30, as illustrated in FIG. 10 (S140). For this, a plating process can be selectively performed or a conductive substance can be selectively printed on the upper surface of the flip-chip bonding pad 14. By way of the flip-chip bonding bump 16, an electrode 32 of the electronic component 30 and the flip-chip bonding pad 14 can be electrically connected to each other.

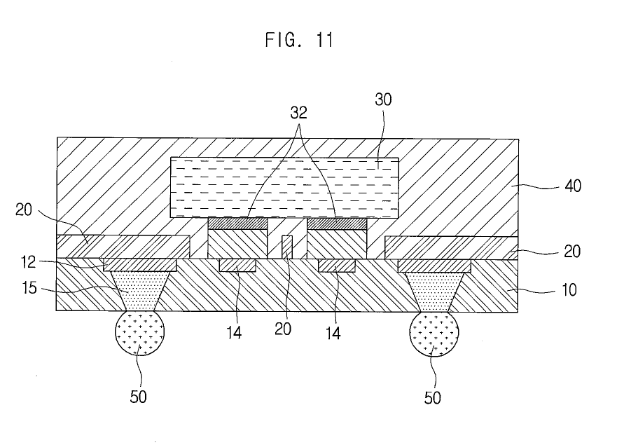

Next, as illustrated in FIG. 11, a solder ball 50 is connected to an end part of the conductive bump 15 having penetrated through the insulator 10 (S150), and the electronic component 30 is mounted on an upper side of the insulator 10 in such a way that the electronic component 30 can be connected to the flip-chip bonding pad 14 through the flip-chip bonding bump 16 by a flip-chip method (S160). That is, the electronic component 30 is not mounted by a face-up method but mounted by a face-down method, and thus the electronic component 30 is connected to the flip-chip bonding pad 14 by the flip-chip bonding bump 16. With this flip-chip connection, more input/output paths can be obtained, making an advantageous structure for higher-density.

Then, the electronic component 30 mounted on an upper side of the insulator 10 can be protected by being covered by a molding material 40.

By utilizing certain embodiments of the present invention as set forth above, higher-density can be implemented, and the production cost can be saved.

While the spirit of the present invention has been described in detail with reference to a particular embodiment, the embodiment is for illustrative purposes only and shall not limit the present invention. It is to be appreciated that those skilled in the art can change or modify the embodiment without departing from the scope and spirit of the present invention.

As such, many embodiments other than that set forth above can be found in the appended claims.

What is claimed is:

1. A single-layer board on chip package substrate comprising:
an insulator;
a circuit pattern and a flip-chip bonding pad formed on an upper surface of the insulator;
a conductive bump being in contact with a lower surface of the circuit pattern and penetrating through the insulator;
a solder resist layer formed on the upper surface of the insulator such that at least a portion of the flip-chip bonding pad is exposed; and
a flip-chip bonding bump formed on an upper surface of the flip-chip bonding pad in order to make a flip-chip connection with an electronic component.

2. The single-layer board on chip package substrate of claim 1, further comprising:
a solder ball coupled to a lower surface of the conductive bump penetrating through the insulator; and
an electronic component mounted on an upper side of the insulator by making a flip-chip connection with the flip-chip bonding pad through the flip-chip bonding bump.

3. The single-layer board on chip package substrate of claim 1, wherein the circuit pattern and the flip-chip bonding pad are buried in the insulator.

4. A method of manufacturing a single-layer board on chip package substrate, the method comprising:
preparing a bump substrate comprising:
forming a circuit pattern and a flip-chip bonding pad on a surface of a carrier;
forming a conductive bump on a surface of the circuit pattern; and
stacking an insulator on the surface of the carrier,
wherein the insulator is penetrated by the conductive bump, and the circuit pattern and the flip-chip bonding pad are buried in the insulator;
removing the carrier such that the circuit pattern and the flip-chip bonding are exposed;
forming a solder resist layer on a surface of the insulator such that the circuit pattern is covered and at least a portion of the flip-chip bonding pad is exposed; and
forming a flip-chip bonding bump on an upper surface of the flip-chip bonding pad in order to make a flip-chip connection with an electronic component.

5. The method of claim 4, further comprising:
coupling a solder ball to an end part of the conductive bump having penetrated through the insulator; and
mounting an electronic component on an upper side of the insulator in such a way that the electronic component makes a flip-chip connection with the flip-chip bonding pad through the flip-chip bonding bump.

6. The method of claim 4, wherein:
the bump substrate is formed in a pair;
the pair of bump substrates are stacked by interposing a separator, prior to the removing of the carrier, wherein an end part of the conductive bump face the separator; and
the pair of bump substrates are separated from the separator, after the forming of the solder resist layer.
